(19) United States
(12) Patent Application Publication
(10) Pub. No.: US 2010/0276793 A1
(43) Pub. Date: Nov. 4, 2010

(54) HIGH PIN DENSITY SEMICONDUCTOR SYSTEM-IN-A-PACKAGE

(76) Inventors: Manolito Galera, Singapore (SG); Leocadio Alabin, Singapore (SG); In Suk Kim, Sommerville (SG)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/432,646

(22) Filed: Apr. 29, 2009

(51) Int. Cl. H01L 23/495; H01L 21/50

(52) U.S. Cl. 257/676; 438/107; 257/E23.037; 257/E21.499

(57) ABSTRACT

Semiconductor packages that contain multiple stacked chips and methods for making such semiconductor packages are described. The packages also contain multiple chips that are stacked vertically. The chips are connected through stud bumps, printed interconnect structures, and conductive pillars formed with the package. The packages also contain two different moldings layers that together operate as an encapsulation material. The semiconductor packages contain a full land pad array at both the bottom and the top of the package, allowing the packages to be used in a package-on-package configuration. The semiconductor packages therefore have a high input/output capability with a small package footprint, and a flexible routing capability. Other embodiments are also described.

### FIELD

This application relates generally to semiconductor devices and methods for making such devices. More specifically, this application describes semiconductor packages that contain multiple, stacked chips and methods for making such semiconductor packages.

### BACKGROUND

Semiconductor packages are well known in the art. Often, these packages may include one or more semiconductor devices, such as an integrated circuit (“IC”) die or chip, which may be connected to a die pad that is centrally formed in a lead frame which contain a series of leads. In some cases, bond wires electrically connect the IC die to a series of terminals that serve as an electrical connection to an external device, such as a printed circuit board (“PCB”). An encapsulating material can be used to cover the bond wires, the IC die, the terminals, and/or other components of the semiconductor device to form the exterior of the semiconductor package. A portion of the terminals and possibly a portion of the die pad may be externally exposed from the encapsulating material. In this manner, the die may be protected from environmental hazards—such as moisture, contaminants, corrosion, and mechanical shock—while being electrically and mechanically connected to an intended device that is external to the semiconductor package.

After it has been formed, the semiconductor package is often used in an ever growing variety of electronic applications, such as disk drives, USB controllers, portable computer devices, cellular phones, and so forth. Depending on the die and the electronic application, the semiconductor package may be highly miniaturized and may need to be as small as possible.

### SUMMARY

This application relates to semiconductor packages that contain multiple stacked chips and methods for making such semiconductor packages. The packages also contain multiple chips that are stacked vertically. The chips are connected through stud bumps, printed interconnect structures, and conductive pillars formed with the package. The packages also contain two different moldings layers that together operate as an encapsulation material. The semiconductor packages contain a full land pad array at both the bottom and the top of the package, allowing the packages to be used in a package-on-package configuration. The semiconductor packages therefore have a high input/output capability with a small package footprint, and a flexible routing capability.

### BRIEF DESCRIPTION OF THE DRAWINGS

The following description can be better understood in light of the Figures, in which:

FIG. 1 shows some embodiments of a method for making semiconductor packages containing a carrier frame with a first interconnect structure;

FIG. 2 depicts some embodiments of a method for making semiconductor packages containing a first die with stud bumps;

FIG. 3 shows some embodiments of a method for making semiconductor packages containing a first molding layer;

FIG. 4 shows some embodiments of a method for making semiconductor packages containing a first via formed in the first molding layer;

FIG. 5 shows some embodiments of a method for making semiconductor packages containing a conductive material formed in the first via;

FIGS. 6 and 7 depict some embodiments of a method for making semiconductor packages containing a second interconnect structure;

FIG. 8 depicts some embodiments of a method for making semiconductor packages with a side view of the structure after the second interconnect structure has been formed;

FIGS. 9 and 10 depict some embodiments of a method for making semiconductor packages containing a second semiconductor die;

FIG. 11 depicts some embodiments of a method for making semiconductor packages containing a third die;

FIGS. 12 and 13 show some embodiments of a semiconductor package containing a second molding layer;

FIG. 14 depicts some embodiments of a semiconductor package containing a second via that has been formed in the second molding layer;

FIG. 15 shows some embodiments of a semiconductor package containing a conductive material that has been formed in the second via;

FIG. 16 depicts some embodiments of a method for making semiconductor packages showing a third interconnect structure;

FIGS. 17 and 18 depict a top and a bottom view of some embodiments of a method for making semiconductor packages showing a singulated package;

FIG. 19 depicts some embodiments of a method for making semiconductor packages showing a singulated package without encapsulation; and

FIG. 20 depicts a side view of some embodiments of a method for making semiconductor packages showing a singulated package without encapsulation.

The Figures illustrate specific aspects of the semiconductor packages and methods for making such packages. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the devices and associated methods of making and using the devices can be implemented and used without employing these specific details. Indeed, the devices and associated methods can be placed into practice by modifying the illustrated devices and associated methods and can be used in conjunction with any other apparatus and techniques conventionally used in the industry. For example, while the description below focuses on methods for making for semiconductor packages in the IC industry, it could be used in and applied to other electronic devices like optoelectronic devices, solar cells, MEMS structures, lighting controls, power supplies, and amplifiers.

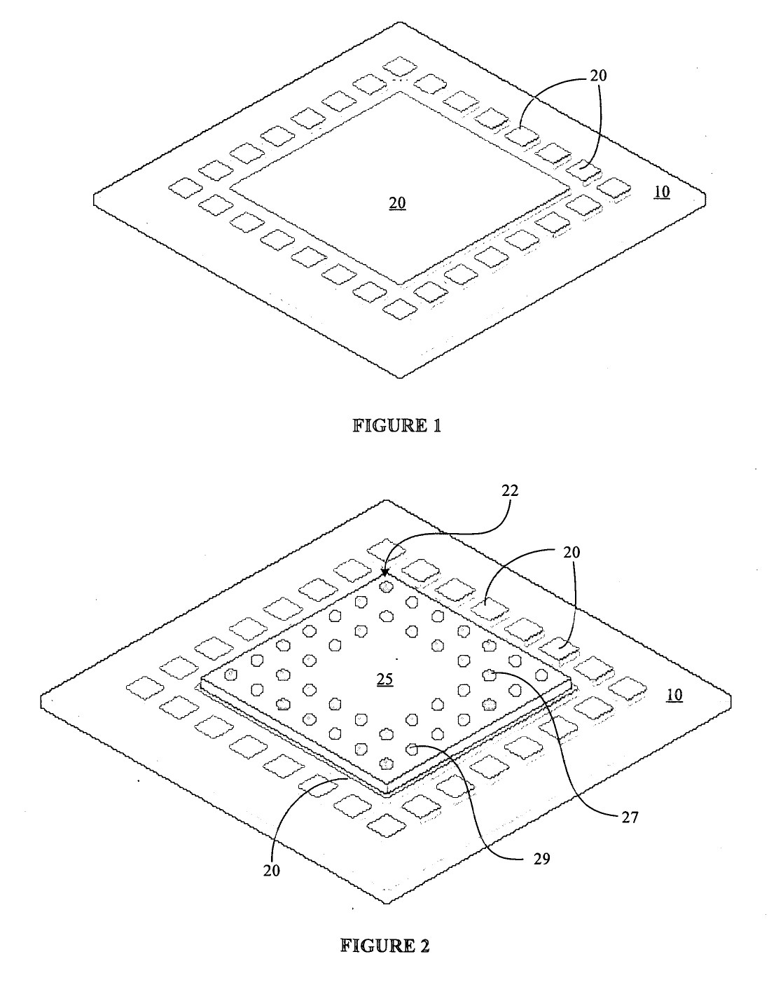

Some embodiments of the semiconductor packages and methods for making such packages are shown in FIGS. 1-20. In these embodiments, the methods for making the semiconductor packages begin by providing a carrier frame (or frame) 10, as shown in FIG. 1. The carrier frame 10 can be any frame that is low-cost, reusable, and can support the process requirements described herein, as well as any frame that can re-used as a substrate for a tape. The carrier frame 10 can be manufactured by any known process, such as a stamping or an etching process.

The carrier frame 10 can have any size and thickness that is needed to operate as a support substrate during the manufacturing process and also be re-usable. Thus, the size and thickness of the carrier frame 10 will depend on the size and density of the semiconductor package, as well as the semiconductor die (or dies) that will be contained in semiconductor package. The carrier frame 10 can comprise any metal or metal alloy known in the art, including Cu, steel alloy (like stainless steel), Ni—Pd, Fe—Ni or combinations thereof. In some embodiments, the frame 10 comprises Cu or steel alloy. In other embodiments, the carrier frame can comprise non-metal materials that can withstand molding temperature and have the required physical strength to support the components of the semiconductor package during assembly process until it is removed. In some embodiments, the lead frame is substantially rectangular with a size ranging from about 9,000 to about 20,000 mm² and a thickness ranging from about 0.15 to about 0.5 mm.

In some embodiments, a tape (not shown in FIG. 1) can optionally be provided on the carrier frame 10. The tape is supported by the carrier frame 10 and so can be made of a flexible or a semi-flexible material. As well, once the semiconductor package is formed, the tape (and the carrier frame) can be removed. So the tape can be made of any material that is partially adhesive, but can be removed when molding process is complete or when it is peeled off without any adhesive material residue left on the molded body. Any material having these characteristics can be used, including polyimide, solder-printable tape, silicone-free tape, or other thin-film materials. While the width and length of the tape can be substantially similar to that of the carrier frame 10, the thickness of the tape can range from about 0.008 mm to about 0.05 mm.

As shown in FIG. 2, a first interconnect structure 20 can then be provided on the frame 10 (and optionally the tape). The first interconnect structure 20 serves to electrically connect a die (or dies) containing an IC device with an external device (i.e., a printed circuit board) in the completed semiconductor package. As well, when the carrier frame 10 and tape are removed, the first interconnect structure 20 will also serve as the land pad array for the semiconductor package. Thus, the interconnect structure 20 can have any pattern that serves both as an interconnect and as a land pad array at the bottom of the semiconductor package.

In some embodiments, the pattern of the first interconnect structure 20 is depicted in FIG. 2. In these embodiments, the interior portion of the pattern contains those parts that will operate as land pads and/or will be connected to a first semiconductor die that will be placed thereon. The exterior portion of the interconnect structure 20 contains those parts that will also operate as land pad arrays and be connected to the first semiconductor die and/or a third semiconductor die in the completed semiconductor package.

The first interconnect structure 20 can be made of any conductive material that can also serve as a land pad. In some embodiments, the first interconnect structure 20 can comprise any electroless plating material, such as Ni—Au, Ni—Ag, or Ni—Au—Ag plating. In other embodiments, the first interconnect structure 20 comprises a printable solderable material, such as Au, Ag, Sn, Pb, Sb, or combinations thereof.

The first interconnect structure 20 can be formed by any process that will provide the desired pattern. In some embodiments, the interconnect structure 20 can be formed by using any known plating process, such as a electroless plating process that uses Ni and Au. In other embodiments, the interconnect structure 20 can be made by any dispensing or screen printing process known in the art.

Next, a semiconductor die 25 (or die) containing an IC device is disposed on the interconnect structure 20. The die 25 may be made of any suitable semiconductor material. Some non-limiting examples of such materials may include silicon, polysilicon, gallium arsenide, silicon carbide, gallium nitride, silicon and germanium, and combinations thereof.

The die 25 can contain any number of IC devices or array of discrete devices. The IC device may be any known integrated circuit in the art. Some non-limiting examples of these devices may include logic or digital IC device, linear regulators, audio power amplifiers, LDO, driver IC, diodes, and/or transistors, including zener diodes, schottky diodes, small signal diodes, bipolar junction transistors (“BJT”), metal-oxide-semiconductor field-effect transistors (“MOSFET”), insulated-gate-bipolar transistors (“IGBT”), and insulated-gate field-effect transistors (“IGFET”).

In some embodiments, the die 25 can contain a redistribution layer. The redistribution layer can be used to re-route the electrical signal from the pattern of the IC device to a different pattern. In some embodiments, the redistribution layer comprises a Ti—Cu under-barrier-metal (UBM), polyimide passivation, and Cu trace/interconnect and is formed by a coating, sputtering and plating/etching process.

The first die 25 is then attached to the interior portion of the first interconnect structure 20. In some embodiments, such as those shown in FIG. 2, the first die 25 is attached to the first interconnect structure 20 by any known die bonding process. In these embodiments, the semiconductor die 25 containing the IC device(s) will be attached to the interior portion of the first interconnect structure 20 by using any known pick & place process. After being attached, the exterior portions of the interconnect structure 20 remain exposed and are not covered by the die 25.

Next, stud bumps 22 are formed on the first die 25, as shown in FIG. 2. The stud bumps 22 can comprise any known material, such as Sn, Pb, Ag, Cu, Sb, Au, or combinations thereof. In some instances, the stud bumps 22 are made of Au and comprise inner stud bumps 27 and outer stud bumps 29. The stud bumps 22 can be formed using any known process, including electroless plating or a printing and reflow process, or a ball-bond type wire bonding process. In some embodiments, solder balls can be used in place of the stud bumps 22. And in some instances, the stud bumps can be formed while the first die 25 is still in its wafer form.

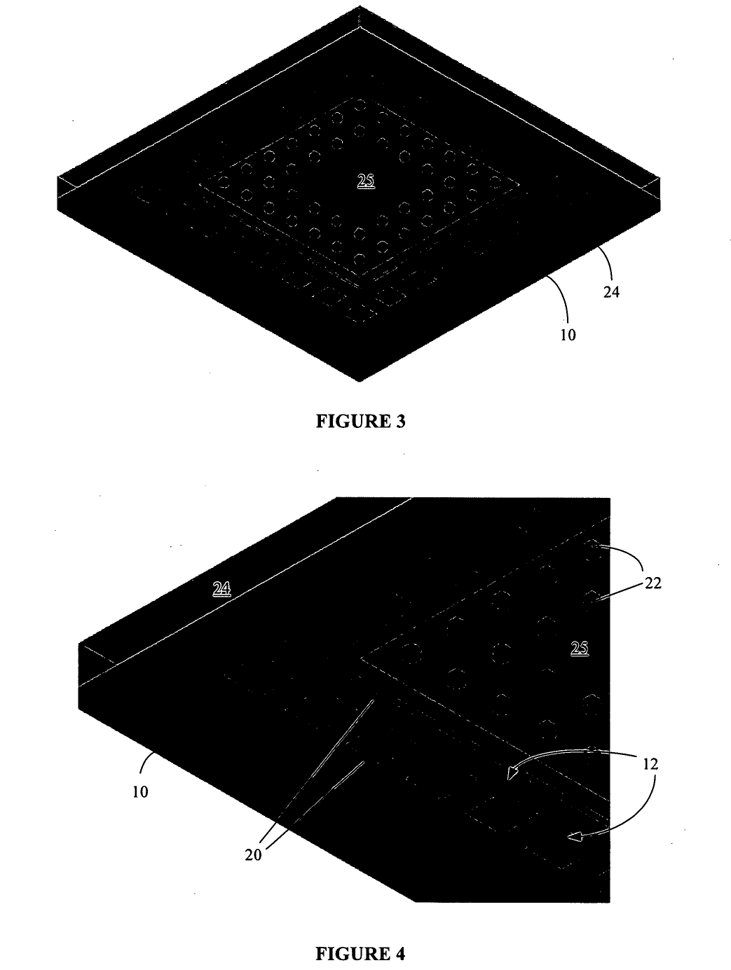

As shown in FIG. 3, a first molding layer 24 can then be provided on the carrier frame 10 (or the tape when it is used), around the first interconnect structure 20, first die 25, and the stud bumps 22 except for the upper surface of the stud bumps 22. The first molding layer 24 can be made of any material known in the art, such as an epoxy molding compound, a thermoset resin, a thermoplastic material, or a potting material. The first molding layer 24 can be provided in any manner known in the art such as transfer molding or compression molding. In some embodiments, the first molding layer 24 is made by a tape assist molding process and then, if necessary, is planarized by any physical action until the upper surfaces of the stud bumps 22 are exposed, as shown in FIG. 3.

Next, as shown in FIG. 4, a first via 12 is then formed in the first molding layer 24 in the areas above the exterior portion of the first interconnect structure 20. The first vias 12 are formed to extend through the first molding layer 24 until the upper surface of the first interconnect structure 20 is reached. The pattern of the first vias 12 can be formed according to the desired land pad location of the final device, including the land pads on the top side and/or the land pads on the bottom side. The first vias 12 can be formed using any process known in the art, including high-precision mechanical drilling or a laser drilling process. The first vias 12 can be formed with any shape known in the art, including cylindrical shape or the shape depicted in FIG. 4.

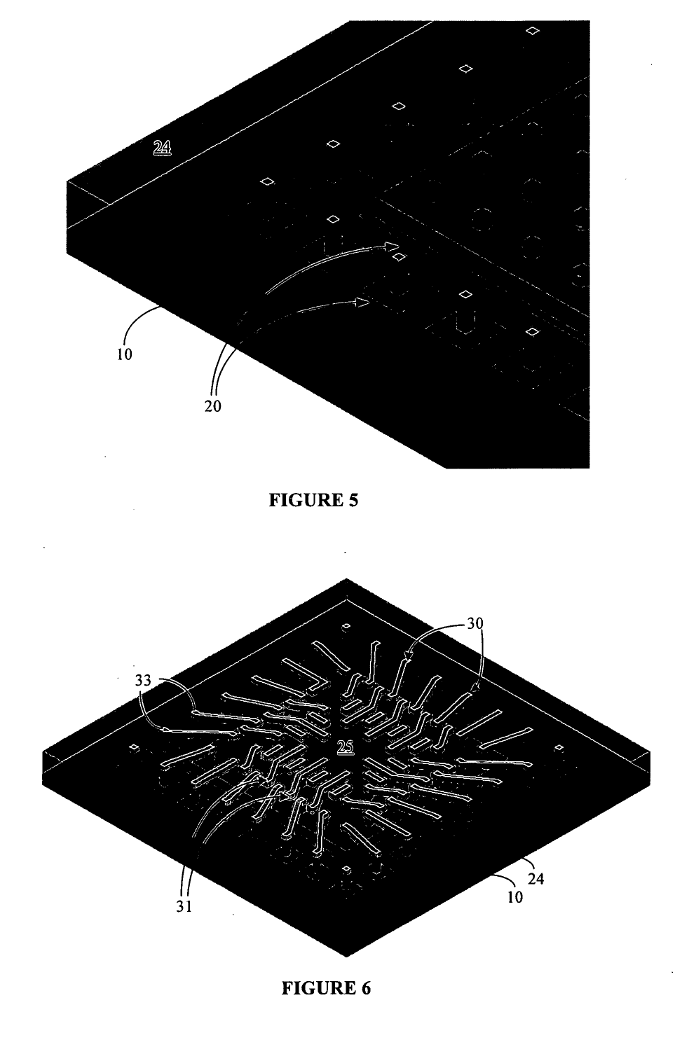

As shown in FIG. 5, the first vias 12 are then filled with a conductive material to form first pillars 14. The conductive material used to make the first pillars 14 can be any conductive material known in the art, including Au, Sn, Pb, Al, Cu, or combinations thereof. The first pillars 14 can be formed using any process known in the art, including by a deposition process followed by a planarization process that leaves the upper surface of the pillars 14 exposed above the first molding layer 24.

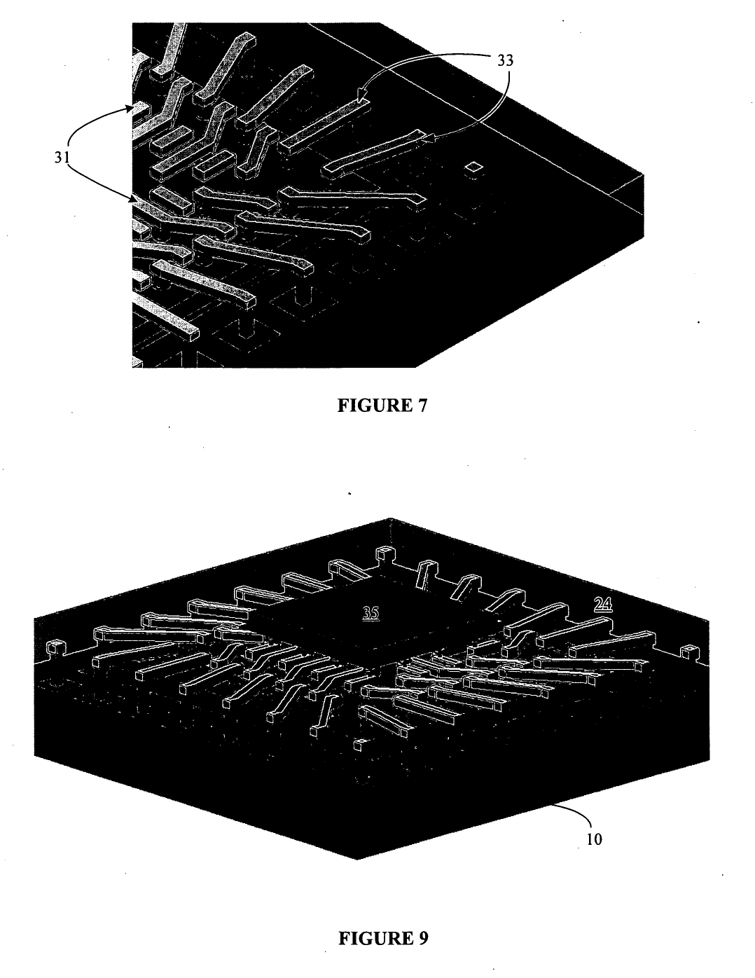

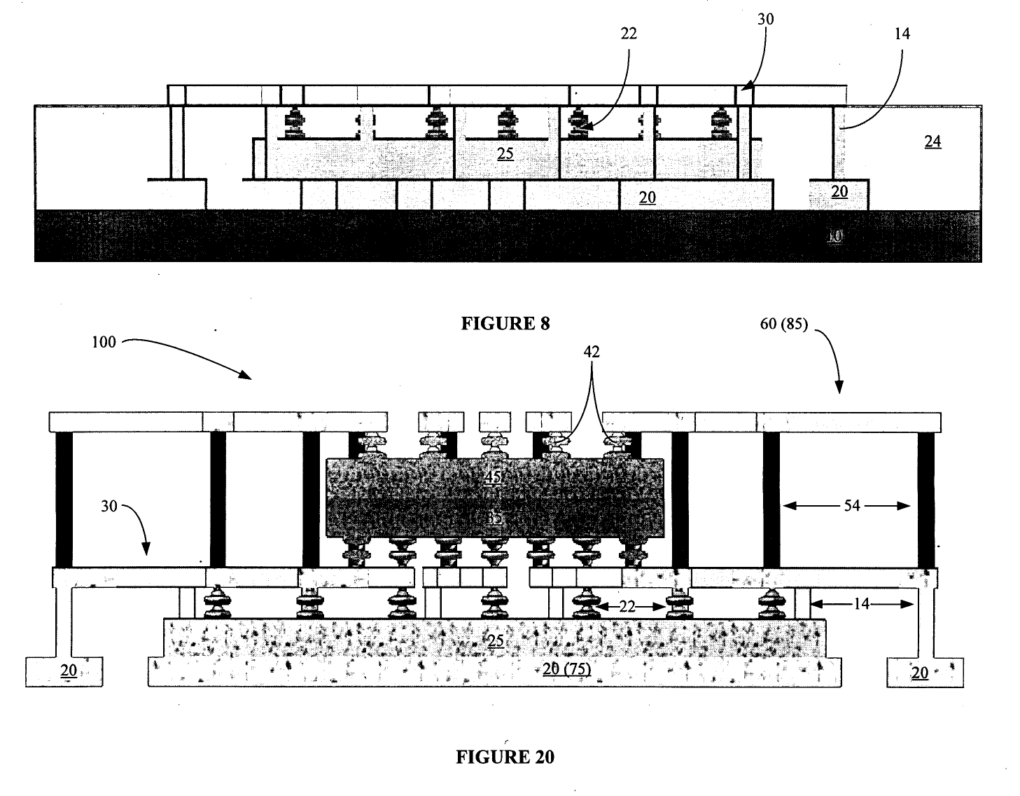

A second interconnect structure 30 can then be provided on the first molding layer 24 and the upper surfaces of the first pillars 14, as shown in FIGS. 6 and 8. The second interconnect structure 30 contains routing leads that serve to electrically connect the exposed upper surfaces of the outer stud bumps 29 of the first die to the exterior portion of the first interconnect structure 20 (which serve as bottom land pads in the completed package) through the first vias 12. The second interconnect structure 30 also connects the inner stud bumps 27 of the first die 25 to a second conductive pillar that will later be formed and used to connect to the lands pads on the top side of the completed semiconductor package. Thus, the second interconnect structure 30 can have any pattern that serves both of these interconnect functions. In some embodiments, the pattern of the interconnect structure 30 is depicted in FIG. 6 (with a close-up in FIG. 7) with inner routing leads 31 (which connect to the inner stud bumps 27) and outer routing leads 33 (which connect to the outer stud bumps 29). The second interconnect structure 30 can be made of any conductive material that is the same or different than the first interconnect structure 20.

The second interconnect structure 30 can be formed by any process that will provide the desired pattern on the first molding layer 24. In some embodiments, the second interconnect structure 30 can be formed by using any known deposition process, masking, and etching process. In other embodiments, the second interconnect structure 30 can be made by any dispensing or screen printing process known in the art.

Next, as shown in FIG. 9, a second semiconductor die (or IC die) 35 is attached to the inner routing leads 31. The second die 35 may be made of the same or different materials than those used in the first die. The second die 35 can contain any number of IC devices that may be the same or different than the device(s) used in the first die 25.

The second semiconductor die 35 can be attached to the inner routing leads 31 using any known flipchip process. In these embodiments, the IC device(s) on the second die 35 can be provided with a bond pad (not shown) as known in the art. In some embodiments, the bond pads can be provided in those areas that overlay the IC device(s). The bond pads can be formed in the desired location by any process known in the art (such as a redistribution method) and can be made of any known solderable material, including Au, Cu, Ag, Ti, Ni, Sn, W, Ni, or combinations thereof.

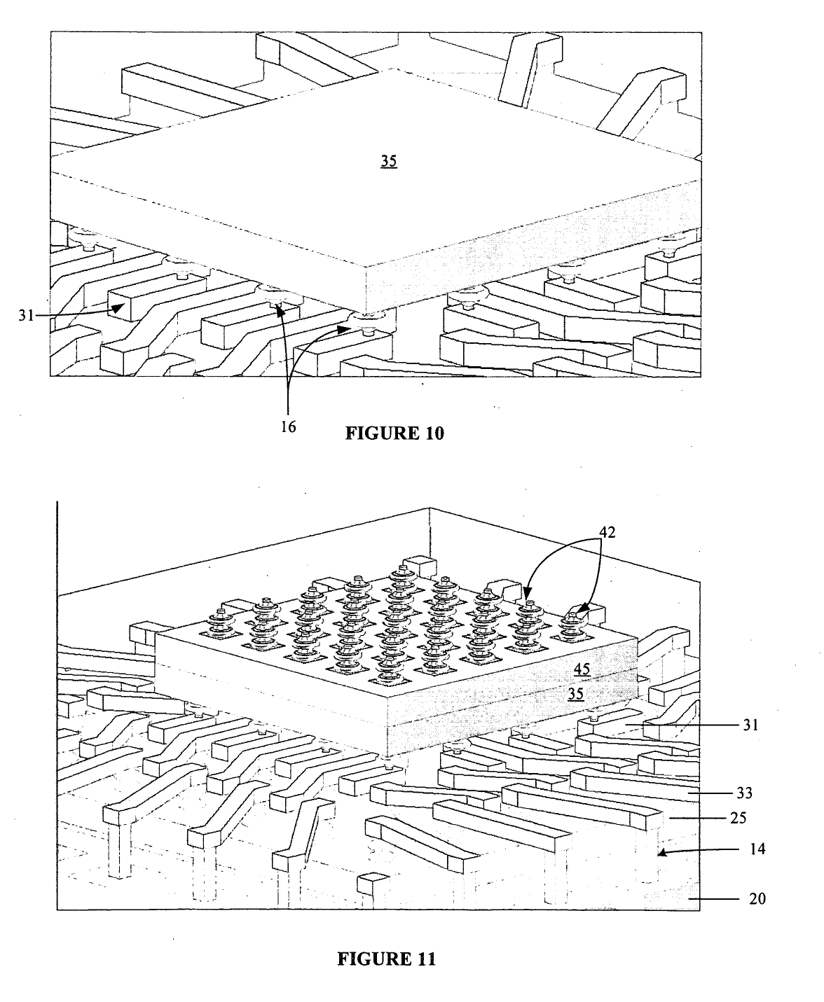

An array of stud bumps 16 (as shown in FIG. 10) can then be provided on the bond pads. The bumps can be made of conductive material such as Ag, Sn, Pb, Cu, Sb, Au or combinations thereof. The bumps can be provided on the bond pads through any process known in the art, including electroless plating, ball drop, ball-bond type wire bonding or printing. Then, the die 35 is flipped and placed on the second interconnect structure 30 so the bond pads (through the bumps) are attached to the desired locations of the routing leads 31 of interconnect structure 30 as shown in FIG. 10.

As shown in FIG. 11, a third semiconductor die (or IC die) 45 is then attached to the backside of the second die 35 through any known process, such as any known pick & place process using an adhesive film or coating on the back side of the wafer. Next, stud bumps 42 are formed on the third die 45, as shown in FIG. 11. The stud bumps 42 can comprise any known material, such as Sn, Pb, Ag, Cu, Sb, Au, or combinations thereof. In some instances, the stud bumps 42 comprise Au. The stud bumps 42 can be formed using any known process, including electroless plating, ball-bond type wire bonding or a printing and reflow process. In some embodiments, solder balls can be used in place of the stud bumps 42. In some configurations, the stud bumps 42 can be formed on the third die 45 before it is attached to the second die 35.

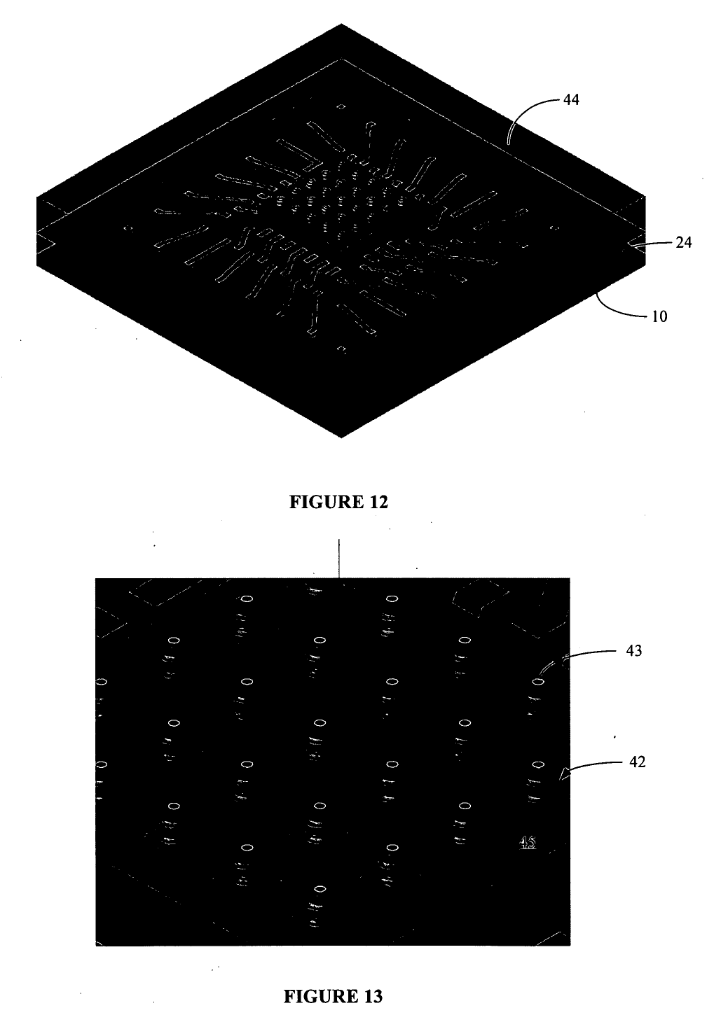

As shown in FIG. 12, a second molding layer 44 can then be provided on the third die 45, around the second interconnect structure 30, and the stud bumps 42 except for the upper surface 43 of the stud bumps 42. The second molding layer 44 can be made of any material known in the art, such as an epoxy molding compound, a thermoset resin, a thermoplastic material, or a potting material. The second molding layer 44 can be provided in any manner known in the art such as transfer molding or compression molding. In some embodiments, the second molding layer 44 is made by a tape assist molding process and then is planarized until the upper surfaces 43 of the stud bumps 42 are exposed, as shown in FIG. 13.

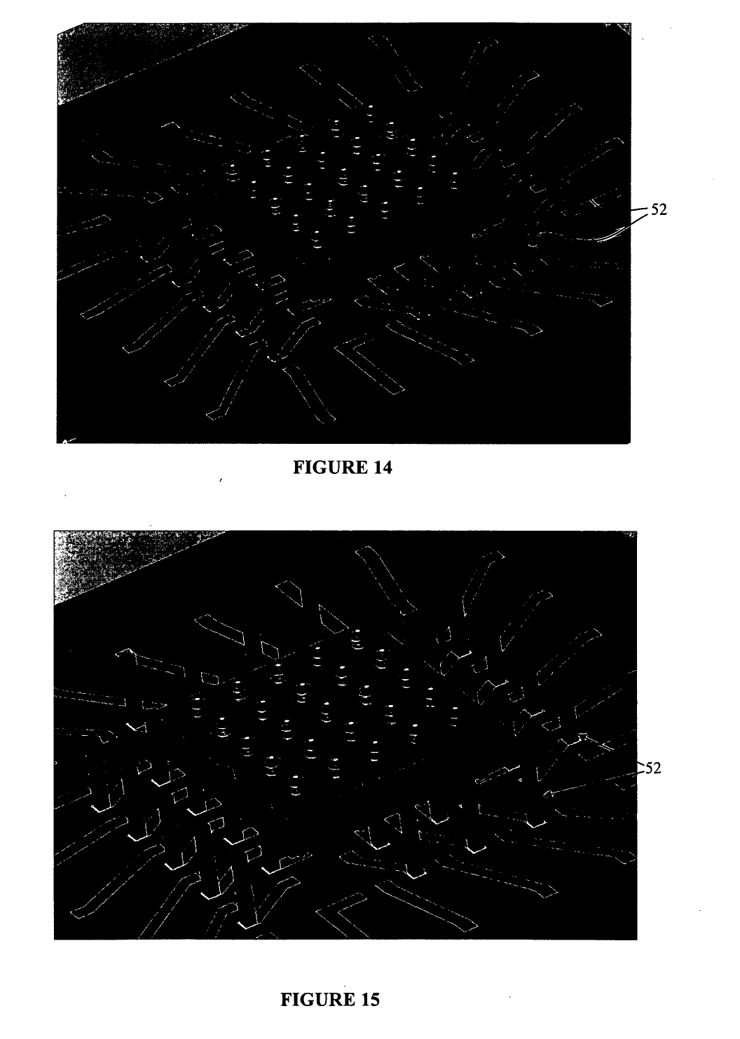

Next, as shown in FIG. 14, a second via 52 is then formed in the second molding layer 44 in the areas above the routing leads 31. The second vias 52 are formed to extend through the second molding layer 44 until the upper surface of the inner routing lead 31 is reached. The pattern of the second vias 52 can be formed according to the desired land pad location of the final device, including the land pads on the top side and/or the land pads on the bottom side. The second vias 52 can be formed using any process known in the art, including high-precision mechanical drilling or a laser drilling process. The second vias 52 can be formed with any shape known in the art, including cylindrical shape or the shape depicted in FIG. 14.

As shown in FIG. 15, the second vias 52 are then filled with a conductive material to form second pillars 54. The conductive material used to make the second pillars can be any conductive material known in the art, including those used for first pillars 14. The second pillars 54 can be formed using any process known in the art, including by a deposition process followed by a planarization process.

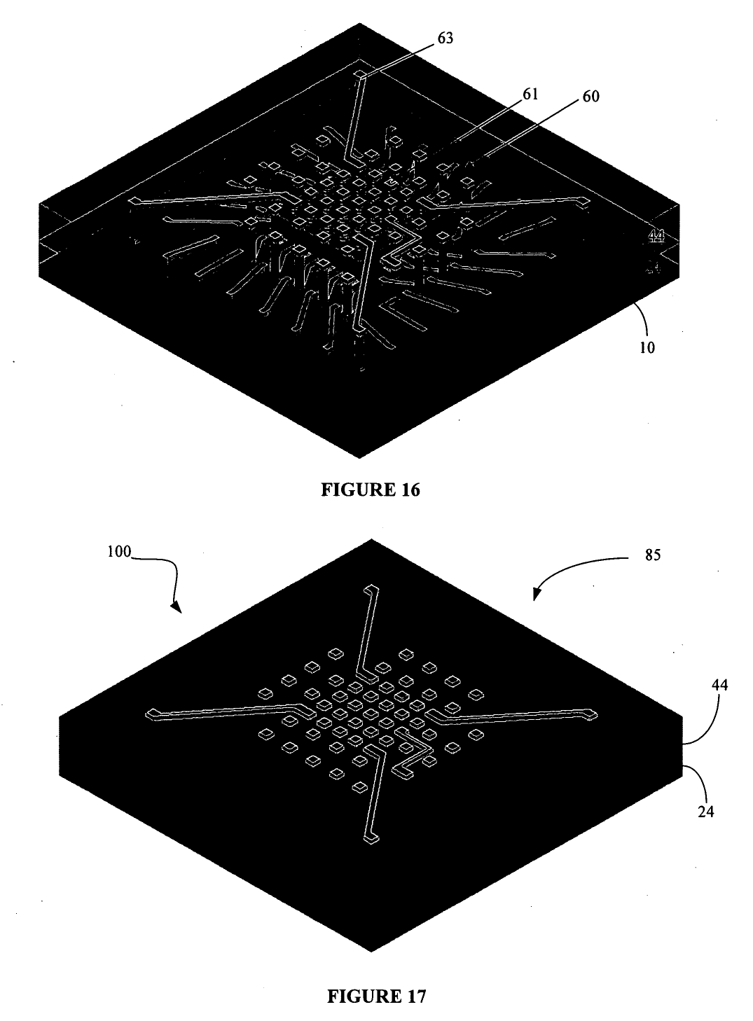

A third interconnect structure 60 can then be provided on the second molding layer 44 and the upper surfaces of the second pillars 54, as shown in FIG. 16. The third interconnect structure 60 contains routing leads that serve as the land pads on the top side of the completed device, electrically connect the exposed surfaces of the stud bumps of the second die 35 to the top land pad array (through the second conductive pillars), electrically connect the exposed surfaces of some of the stud bumps 42 of the third die 45 to the top land pad array, and to electronically connect other stud bumps to the bottom land pads via the first and second conductive pillars. Thus, the third interconnect structure 60 can have any pattern that serves these functions. In some embodiments, the pattern of the third interconnect structure 60 is depicted in FIG. 16 with inner routing leads 61 and outer routing leads 63. The third interconnect structure 60 can be made of any conductive material that is the same or different than the first and/or second interconnect structures.

The third interconnect structure 60 can be formed by any process that will provide the desired pattern on the second molding layer 44. In some embodiments, the third interconnect structure 60 can be formed by using any known deposition process, and known masking and etching process. In other embodiments, the third interconnect structure 60 can be made by any dispensing or screen printing process known in the art.

The process for making the semiconductor package continues when the carrier frame 10 (and optionally the tape) is removed. In this process, one or both of these components can be removed by any process that will not damage the structure that remains after their removal. In some embodiments, the removal process can be performed by peeling off the tape and the carrier frame using a tape remover machine with automatic handling system. Optionally, a plating process can form a plate or coating on the bottom and/or top land pads to provide protection from corrosion and at the same time provide a solder-ready surface lands.

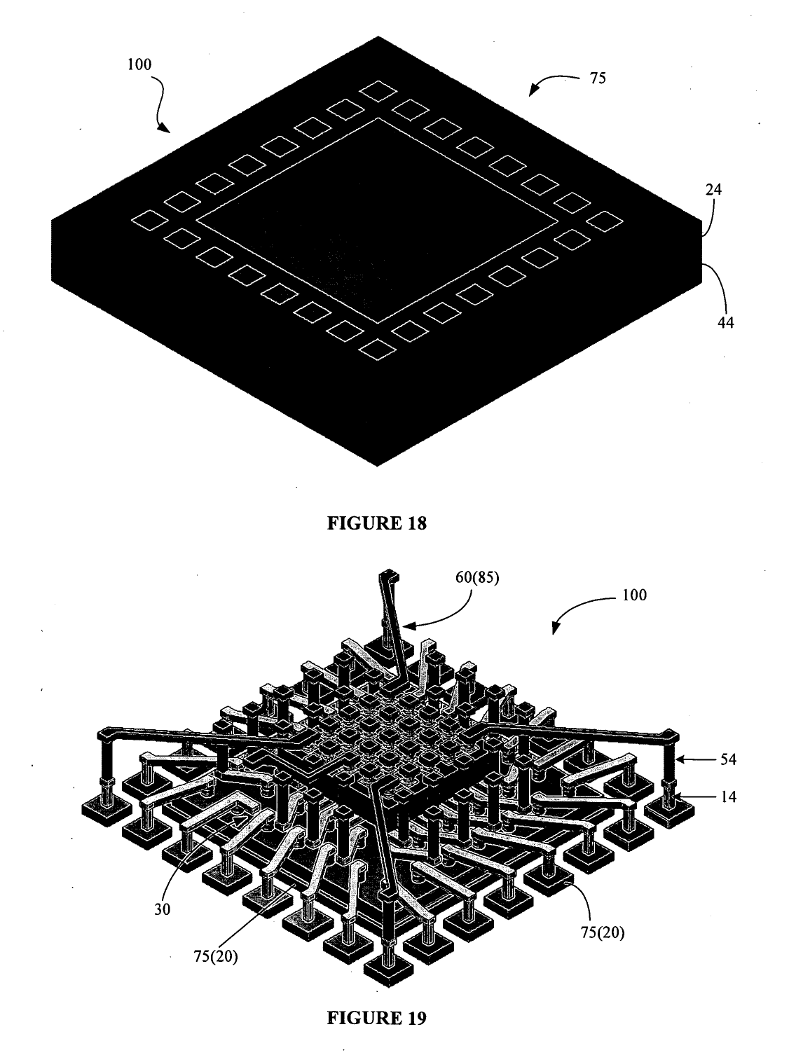

The removal of the carrier frame 10 (and the tape) leaves the pattern of the first interconnect structure 20 exposed on the bottom of the package since neither of the molding layers encapsulate the bottom surface of the interconnect structure 20. Thus, the bottom surface contains an array of land pads or lands 75, as shown in FIG. 18. The land pads 75 can have any other configuration or layout known in the art consistent with their operation in the semiconductor package.

As well, the pattern of the third interconnect structure 60 is also left exposed on the top side of the completed package because it is formed on the second molding layer 44. Thus, the top surface contains an array of land pads or lands 85, as shown in FIG. 17. The land pads 85 can have any other configuration or layout known in the art consistent with their operation in the semiconductor package. The first and second molding layers work together to encapsulate the internal components except for the bottom land pads 75 and the top land pads 85.

The completed semiconductor package 100 is then singulated. The singulation of the semiconductor package can be carried out using any process known in the art, including a saw singulation process or a water jet singulation process or a laser-cut singulation method. Then, the singulated semiconductor packages may be electrically tested, taped, and reeled using any processes known in the art. The semiconductor packages can then be connected to a printed circuit board using any known connection (i.e., solder connectors) and used in any electronic device known in the art such as portable computers, disk drives, USB controllers, portable audio devices, or any other portable/ultraportable electronic devices.

The completed semiconductor package 100 (without the first and second molding layers) is shown in the top view of FIG. 19 and the side view of FIG. 20. The package 100 contains the first semiconductor die 25 where the IC device(s) is connected through the first pillars 14 and the routing leads 33 to the lands pads 75 that have been formed from the exterior potion of the interconnect structure 20. The inner portion of the land pads 75 operates as thermal pad when connected to the PCB. The pattern of the interconnect structure 20 can be routed and customized for a wide variety of land configurations. This allows the semiconductor package 100 to be configured with many different sizes and shapes and used with different die sizes and shapes.

The IC device(s) in the second die 35 of the package 100 is connected to the routing leads 31 of the second interconnect structure 30. The routing leads 31 are, in turn, connected to the third interconnect structure 30 (which also forms top land pads 85) through second pillars 54. The IC device(s) in the third die 45 are connected to both the bottom land pads 75 and the top land pads 85 through the third interconnect structure 60. The land pads 75 and 85 remain exposed and are configured in a stand-off position so that they can be attached to the PCB or other external device as known in the art.

The semiconductor packages formed by these methods have several features. First, because the land pad array is located on both the top and bottom, the packages can be used in a package-on-package configuration. Second, these packages contain multiple semiconductor dies that can be stacked on each other, yet do not use long wirebonds that are often used with stacked dies. Third, the packages are also relatively thin while also having the capability of a full land pad array at both the bottom and the top of the packages. These features provide a high input/output (I/O) capability, flexible routing capability, smaller package footprint, and a cost effective manufacturing solution.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A semiconductor package, comprising:
a bottom land pad array comprising an inner portion and an outer portion;
a first die connected to the outer portion of the bottom land pad array through first routing leads and a first conductive pillar array;
a second die disposed over the first die and resting on second routing leads that are connected to a top land pad array by the second routing leads and a second conductor pillar array;
a third die disposed on the backside of the second die and directly connected to the top land pad array and connected to the bottom land pad array through the first and second conductive pillars; and
a molding material.

2. The semiconductor package of claim 1, wherein the bottom land pad array and the top bond pad array are both a full land pad array.

3. The semiconductor package of claim 1, wherein the molding material comprises a first molding layer encapsulating the bottom land pad array except for the bottom surface, the first die, the first conductive pillar array, and first stud bumps on the first die except for an upper surface thereof; and

4. The semiconductor package of claim 3, wherein the molding material comprises a second molding layer encapsulating the top land pad array except for the top surface, the second die, the third die, the second conductive pillar array, and third stud bumps on the third die except for an upper surface thereof.

5. The semiconductor package of claim 4, wherein the first portion and the second portion of the molding material are formed separately.

6. The semiconductor package of claim 3, wherein the first stud bumps are connected to the first routing leads.

7. The semiconductor package of claim 1, wherein the second die contains second stud bumps that are connected to the second routing leads.

8. The semiconductor package of claim 4, wherein the third stud bumps are connected to the top land pad array.

9. An electronic device containing a semiconductor package, comprising:
a bottom land pad array comprising an inner portion and an outer portion;
a first die connected to the outer portion of the bottom land pad array through first routing leads and a first conductive pillar array;
a second die disposed over the first die and resting on second routing leads that are connected to a top land pad array by the second routing leads and a second conductor pillar array;
a third die disposed on the backside of the second die and directly connected to the top land pad array and connected to the bottom land pad array through the first and second conductive pillars; and
a molding material.

10. The electronic device containing of claim 9, wherein the bottom land pad array and the top bond pad array are both a full land pad array.

11. The electronic device containing of claim 9, wherein the molding material comprises a first molding layer encapsulating the bottom land pad array except for the bottom surface, the first die, the first conductive pillar array, and first stud bumps on the first die except for an upper surface thereof; and

12. The electronic device containing of claim 11, wherein the molding material comprises a second molding layer encapsulating the top land pad array except for the top surface, the second die, the third die, the second conductive pillar array, and third stud bumps on the third die except for an upper surface thereof

13. The electronic device containing of claim 12, wherein the first portion and the second portion of the molding material are formed separately.

14. The electronic device containing of claim 11, wherein the first stud bumps are connected to the first routing leads.

15. The electronic device containing of claim 9, wherein the second die contains second stud bumps that are connected to the second routing leads.

16. The electronic device containing of claim 12, wherein the third stud bumps are connected to the top land pad array.

17. A method for making a semiconductor package, comprising:
providing a bottom land pad array comprising an inner portion and an outer portion;
providing a first die connected to the outer portion of the bottom land pad array through first routing leads and a first conductive pillar array;
providing a second die disposed over the first die and resting on second routing leads that are connected to a top land pad array by the second routing leads and a second conductor pillar array;
providing a third die disposed on the backside of the second die and directly connected to the top land pad array and connected to the bottom land pad array through the first and second conductive pillars; and
a molding material.

18. A method for making semiconductor package, comprising:
providing a carrier frame;
forming a first interconnect structure on the tape, the first interconnect structure comprising an inner portion and an outer portion;
attaching a first die containing first stud bumps to the inner portion of the first interconnect structure;
providing a first molding layer around the first die and the first stud bumps except for an upper surface of the first stud bumps;
forming first conductive pillars from the outer portion of the first interconnect structure to the upper surface of the first molding layer;
providing a second interconnect structure that contacts the upper surface of the first stud bumps and the upper surface of the first conductive pillars;
attaching a second die containing second stud bumps to the second interconnect structure;
attaching the back side of a third die containing third stud bumps on the front side to the backside of the second die;
providing a second molding layer around the second die, third die, and the third stud bumps except for an upper surface of the third stud bumps;
forming second conductive pillars from the second interconnect structure to the upper surface of the second molding layer; and
providing a third interconnect structure that contacts the upper surface of the third stud bumps and the upper surface of the second conductive pillars.

19. The method of claim 18, further comprising removing the carrier frame and the tape.

20. The method of claim 18, including connecting the second die to the second interconnect structure by a flipchip process.

21. The method of claim 18, wherein the first and second molding layers encapsulate the semiconductor package except for the bottom of the first interconnect structure and the top of the third interconnect structure.

22. The method of claim 18, wherein the second interconnect structure contains inner routing leads and outing routing leads.

23. The method of claim 18, wherein the third interconnect structure contains inner routing leads and outing routing leads.

24. The method of claim 18, including forming the first conductive pillars by laser drilling first vias in the first molding layer and then filling the first vias with a conductive material.

25. The method of claim 18, including forming the second conductive pillars by laser drilling second vias in the second molding layer and then filling the second vias with a conductive material.
